(19) United States
(12) Patent Application Publication
(10) Pub. No.: US 2004/0251549 A1
(43) Pub. Date: Dec. 16, 2004

(54) Hybrid copper/low k dielectric interconnect integration method and device

(76) Inventors: Tai-Chun Huang, Hsin-Chu (TW); Chih-Hsiang Yao, Hsin-Chu (TW); Kang-Cheng Lin, Hsin-Chu (TW); Chin Chiou Hsia, Hsin-Chu (TW); Mong Song Liang, Hsin-Chu (TW)

Correspondence Address: SLATER & MATSIL, L.L.P., 17950 PRESTON ROAD, SUITE 1000, DALLAS, TX, 75252, US

(21) Appl. No.: 10/602,751

(22) Filed: Jun. 24, 2003

Related U.S. Application Data
(60) Provisional application No. 60/477,713, filed on Jun. 11, 2003.

(51) Int. Cl. H01L 27/15

(52) U.S. Cl. 257/758

(57) ABSTRACT

A multiple layer metal interconnect process provides for both good electrical properties and good mechanical properties by using a first extremely low k dielectric material at the lower level metal layers, a second extremely low k dielectric material at the middle level metal layers, and a low k dielectric material at the upper level metal layers.

### TECHNICAL FIELD

The present invention relates generally to the field of semiconductor devices and more particularly to semiconductor devices having a multi-level metallization stack in which different inter-level dielectric layers having differing mechanical and electrical properties are employed.

### BACKGROUND

The dielectric constant, k, is a value of a material's insulating properties. Low k dielectric materials are becoming increasingly popular in integrated circuits because of the improved electrical performance that can be obtained through the use of low k dielectrics as inter-metal or inter-level insulating material. For instance, the RC time constant of a device or circuit employing low k dielectrics can be substantially reduced over traditional inter-level dielectrics, thus allowing for faster switching speeds and improved device performance.

Low k dielectric materials involve a trade-off, however, because such materials typically have relatively poor mechanical properties compared to traditional dielectrics. Generally, the lower the dielectric constant, the poorer the mechanical strength of the material. This is because the low k dielectric constant is typically achieved as a result of materials having a relatively high degree of porosity. The more porous the material, the lower its dielectric constant, but also the lesser its mechanical strength. Typically, the cracking threshold is lower for a low k dielectric material and the coefficient of thermal expansion is greater. Additionally, the increased porosity of the materials results in poor adhesion with subsequently applied thin films. These properties of low k dielectric materials (aka low k dielectrics) are an undesirable trade-off for the improved electrical characteristics.

In modern semiconductor devices, low k dielectric materials are used as inter-level, also known as inter-metal, dielectrics to insulate one metal level from another. As is well known in the art, metal levels are stacked atop one another to form the complete integrated circuit, with the inter-level dielectric layers acting as an insulating material there between. In damascene metallization processes, the inter-level dielectric material also acts as a supporting layer in which the metal traces are formed. Integrated circuits having six, eight, and an even greater number of stacked metal layers are known in the art. Trends suggest that the number of stacked metal layers will increase over time.

Typically, a single dielectric material, such as fluorine-doped silica glass (FSG) or undoped silicon glass (USG) will be employed throughout the stacked metal layers of a conventional multi-metal-layer integrated circuit. In other words, if FSG is used between the first and second metal layers, the same FSG material will be used between the second and third metal layers and between all subsequently deposited metal layers. In some devices, the inter-level dielectric material used between metal layers will be a composite of more than one dielectric material. In such devices, however, the same composite material will be used throughout the metal layers, from bottom to top.

The trend toward a higher number of stacked metal layers and the increasingly stringent performance and reliability requirements for integrated circuits exacerbates the problem of the poor mechanical properties of low k dielectric materials. What is needed, therefore, is an integration scheme that is compatible with present manufacturing processes, but that allows for stacking of multiple metal layers with preferred low k dielectric constant inter-level materials having acceptable mechanical strength and stability.

### SUMMARY OF THE INVENTION

In one aspect, the present invention provides for an integrated circuit comprising a substrate having a top surface and a first dielectric layer formed above the substrate having a trench formed therein. The first dielectric layer has a first dielectric constant. A first metal layer is formed within the trench of the first dielectric layer. The integrated circuit further includes a second dielectric layer formed above the first metal layer and having a trench formed therein, the second dielectric layer having a second dielectric constant. A second metal layer is formed within the trench of the second dielectric layer. The integrated circuit also includes a third dielectric layer formed above the second metal layer and having a trench formed therein, the third dielectric layer having a third dielectric constant, and a third metal layer formed within the trench of the first dielectric layer.

In another aspect, the present invention provides for a method of forming an integrated circuit comprising forming a transistor within a substrate, depositing a first dielectric material over the transistor, forming an opening to the transistor in the first dielectric material, and depositing a first metal pattern within the first dielectric material. The method further includes depositing a second dielectric material having a higher dielectric constant than the first dielectric material over the first metal pattern, forming an opening to the first metal pattern in the second dielectric material, and depositing a second metal pattern within the second dielectric material. The method also includes depositing a third dielectric material having a higher dielectric constant than the first and second dielectric material over the second metal pattern, forming an opening to the second metal pattern in the third dielectric material, and depositing a third metal pattern in the third dielectric material.

In yet another aspect, the present invention provides for an integrated circuit. The integrated circuit includes a substrate and a plurality of transistors formed on the substrate, and a plurality of isolation regions electrically isolating at least one of the plurality of transistors from at least one other of the transistors. The integrated circuit includes a first dielectric layer having a first dielectric constant formed above the substrate and having formed therein a via to a transistor, and an interconnect structure. The integrated circuit further includes a second dielectric layer having a second dielectric constant formed above the first dielectric layer and having formed therein a second interconnect structure, and a third dielectric layer having a second dielectric constant formed above the second dielectric layer and having formed therein a third interconnect structure.

An advantageous feature of the present invention is that in those regions where the dielectric constant is of most importance, materials having very good electrical characteristics, albeit with less than ideal mechanical characteristics can be employed, whereas in those regions where electrical performance of the dielectric is not as critical, other dielectric materials—having acceptable dielectric properties and improved mechanical properties—can be employed. In this way, the selected dielectric material employed provides for the best combination of electrical and mechanical properties, depending upon the needs of the specific metal layer(s) in which the dielectric is to be employed.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates in cross-section an integrated circuit in which a preferred embodiment of the present invention is provided; and

FIGS. 2a through 2h illustrate in cross-section stages of the manufacture of preferred embodiment devices.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention. For ease of reference, common reference numerals will be used throughout the figures when referring to the same or similar features common to the figures.

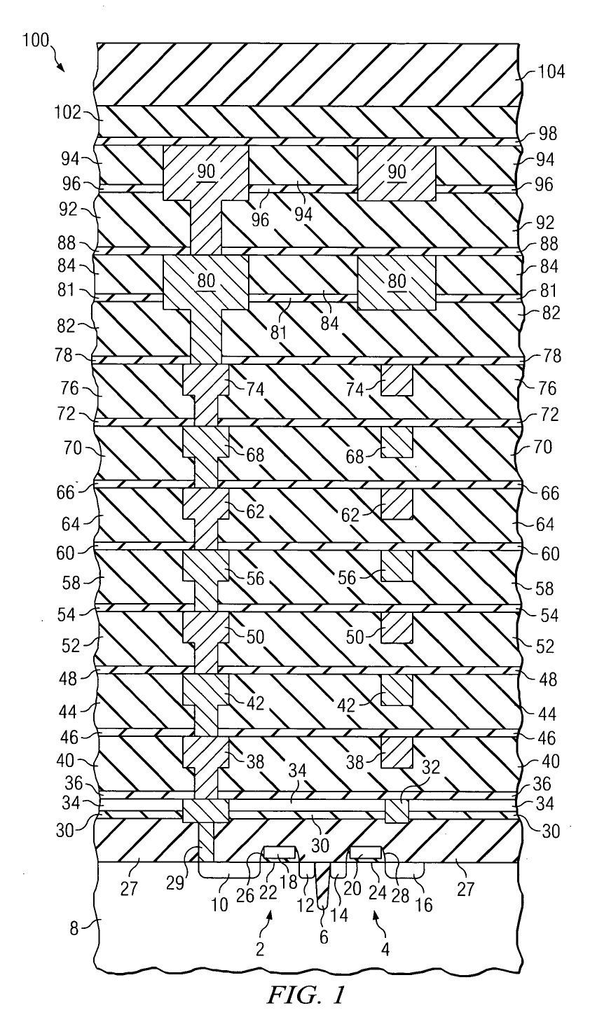

FIG. 1 illustrates a portion of an integrated circuit embodying aspects of the present invention. In particular, device 100 includes a first transistor 2 and a second transistor 4, separated by an isolation region 6, all formed within substrate 8. Substrate 8 is illustrated as a single semiconductor wafer, such as a single crystal silicon wafer. Alternatively, substrate 8 could comprise a thin silicon layer formed over a buried oxide, such as a silicon-on-insulator (SOI) substrate. Many details regarding first and second transistors 2 and 4, respectively, are omitted because they are not necessary for an understanding of the invention. One skilled in the art will recognize that transistors 2 and 4 could be formed using conventional CMOS processing technology and could form the basic components of, e.g., a CMOS inverter. Doped regions 10, 12 of transistor 2 and doped regions 14, 16 of transistor 4 could be formed of N-type and P-type impurities, respectively, for instance. Gate 18 of transistor 2 and gate 20 of transistor 4 is preferably a polysilicon gate electrode separated from the substrate by a thin gate oxide (22 and 24, respectively) and preferably having sidewall spacers (26 and 28, respectively) providing further insulation as are well known in the art. Of particular significance, device 100 includes a stack of ten metallization layers. These metallization layers will interconnect transistors 2 and 4 to other transistors and devices (not shown) on the integrated circuit, including ground nodes and voltage nodes, but will also connect the various components of the integrated circuit to circuitry, signals, and voltages external to the integrated circuit device.

Dielectric layer 27 overlies and electrically insulates the transistors 2 and 4 (and other components and devices formed within or on substrate 8) from subsequently formed layers, such as metal layer 32.

Electrical contact to the transistors and other devices formed within or on substrate 8 is accomplished by way of contacts 29 through etch stop layer 30 and dielectric layer 27. In the illustrated embodiment only one contact is shown connecting to doped region 10 of transistor 2, for clarity. One skilled in the art will recognize that multiple contacts will be made to the devices, including connection to other doped regions and to the gates, although these have been omitted from the drawings for clarity. First metal pattern 32 is formed above the transistors and is electrically coupled to the transistors via contacts 29. This first metal pattern is electrically insulated from subsequently formed metal patterns, such as second metal pattern 38, by dielectric layer 34 and etch stop layer 36, and by dielectric layer 40.

In the preferred embodiments, dielectric layer 40 is preferably an extremely low k dielectric material, preferably having a dielectric constant of below 2.8 and even more preferably having a dielectric constant in the range of 2.2 to 2.5. Extremely low k dielectric layer 40 is preferably formed of an oxide and methylsilsesquioxane (“MSQ”) hybrid, an MSQ derivative, porogen/MSQa hybrid, an Oxide/Hydrogen silsesquioxane (“HSQ,” also known as Hydridosilsesquioxane) hybrid, an HSQ derivative, a porogen/HSQ hybrid, and the like. Other materials, such as nanoporous silica, xerogel, poly tetra fluoro ethylene (“PTFE”), and low k dielectrics such as SiLK available from Dow Chemicals of Midland, Mich., Flare, available from AlliedSignal of Morristown, N.J., and Black Diamond, available from Applied Materials of Santa Clara, Calif., may also be employed. The layers are preferably deposited using a chemical vapor deposition (“CVD”) or spin-on coating technique, although other deposition techniques could be employed as well. In the presently contemplated preferred embodiments, the middle-level dielectric layers are preferably deposited to a thickness of approximately 2,000 to 9,000 Angstroms. One skilled in the art will recognize that the preferred thickness range will be a matter of design choice and will likely decrease as device critical dimensions shrink and processing controls improve over time. Materials such as these provide for exceptionally good electrical characteristics, such as low RC constants and hence fast switching speeds. These materials suffer from less than ideal mechanical properties, however.

Subsequently formed metal pattern 42 is formed within dielectric layer 44 and electrically insulated from metal layer 38 (except for those regions in which electrical contact is desired) by dielectric layer 44. This dielectric layer and dielectric layer 52 in which subsequently formed metal pattern 50 is formed are preferably formed from the same extremely low k dielectric material as layer 40. Also shown in FIG. 1 are etch stop layers 46, 48 and 54, which are used to protect the dielectric layers 40, 44 and 52, respectively, during etching of trenches in the subsequently formed dielectric layers 44, 52 and 58, respectively, as will be explained in greater detail below.

Turning now to dielectric layer 58, in which metal pattern 56 is formed. This layer, being formed in the middle region of the ten layer stack, requires both good electrical characteristics (i.e., low k) and also good mechanical performance. At the mid-level layers, the device performance is not as subject to the dielectric constant as at the lower metal layers. As such, the inter-level dielectric at these layers can be formed of a material having electrical characteristics (i.e., dielectric constants) that are not as low as the lower level dielectrics (40, 44, 52), but which have improved mechanical properties. In the preferred embodiments, mid-stack dielectric layer 58, as well as layers 64, 70 and 76 in which are formed mid-stack metal patterns 56, 62, 68 and 74, respectively, are formed of a different extremely low k dielectric material preferably having a dielectric constant in the range of between 2.5 and 4.2 and even more preferably in the range of between 2.5 and 3.3 (using etch stop layers 60, 66 and 72, respectively). Extremely low k dielectric layers 58, 64, and 70 are preferably formed of an oxide and methylsilsesquioxane (“MSQ”) hybrid, an MSQ derivative, porogen/MSQa hybrid, an Oxide/Hydrogen silsesquioxane (“HSQ,” also known as Hydridosilsesquioxane) hybrid, an HSQ derivative, a porogen/HSQ hybrid, and the like. Other materials, such as nanoporous silica, xerogel, poly tetra fluoro ethylene (“PTFE”), and low k dielectrics such as SiLK available from Dow Chemicals of Midland, Mich., Flare, available from AlliedSignal of Morristown, N.J., and Black Diamond, available from Applied Materials of Santa Clara, Calif., may also be employed. The layers are preferably deposited using a chemical vapor deposition (“CVD”) or spin-on coating technique, although other deposition techniques could be employed as well. In the presently contemplated preferred embodiments, the middle-level dielectric layers are preferably deposited to a thickness of approximately 2,000 to 7,000 Angstroms. One skilled in the art will recognize that the preferred thickness range will be a matter of design choice and will likely decrease as device critical dimensions shrink and processing controls improve over time.

At the upper end of the metal layer stack the dielectric constant of the inter-level dielectrics—while still important—becomes less critical. As such, inter-level dielectrics with a higher dielectric constant can be tolerated in order to employ materials having even further improved mechanical characteristics. In the preferred embodiments, dielectric layers formed at or near the top of the multi-layer metal stack are preferably formed using a dielectric material that has acceptable electrical characteristics, albeit relatively higher than the extremely low k dielectrics used lower in the stack. Preferably, dielectric layers 94, 92, 84, and 82 (being the top several dielectric layers in which are formed metal patterns 90 and 80, respectively) are formed of a material having a dielectric constant in the range of about 3.0 to 4.2. One exemplary such material is undoped silicon glass (USG) that can be spun onto the substrate surface and subsequently patterned. In other instances, FSG or other well known alternatives, having acceptably low k characteristics, may be employed. While the layer thickness is a matter of design choice and process control, the upper layers would be typically deposited to a thickness in the range of from 6,000 to 15,000 Angstroms. Note that etch stop layers 78, 81, 88, and 98 are employed in the damascene process, as described above.

Note that, as illustrated in FIG. 1, metal layers one through eight (i.e., layers 32, 38, 42, 50, 56, 62, 68, and 74) are illustrated as having been formed using dual damascene processing (i.e., both the via and the interconnect trench are formed together), whereas top metal layers 80 and 90 are shown as having been formed using a single damascene process. One skilled in the art will recognize that other variations between dual damascene and single damascene, trench first or via first, and other process variations are matters of design choice.

Finally, as illustrated in FIG. 1, an etch stop layer 98 is formed over top level metal pattern 90. Passivation layers 102 and 104 are then formed over the top level metal as is known in the art. These passivation layers 102 and 104 are preferably formed of plasma enhanced SiN and plasma enhanced undoped silicon glass (USG) respectively.

Note that in FIG. 1, the metal patterns at the bottom of the stack (e.g., 32) are small relative to the metal patterns at the top of the stack (e.g., 90). This is because there is a significantly greater number and density of interconnections at the lower levels of the stack. This causes a greater packing density for the lower level metal patterns (i.e., smaller feature sizes and closer spacings). This in turn increases the need for the improved electrical and dielectric characteristics as described herein.

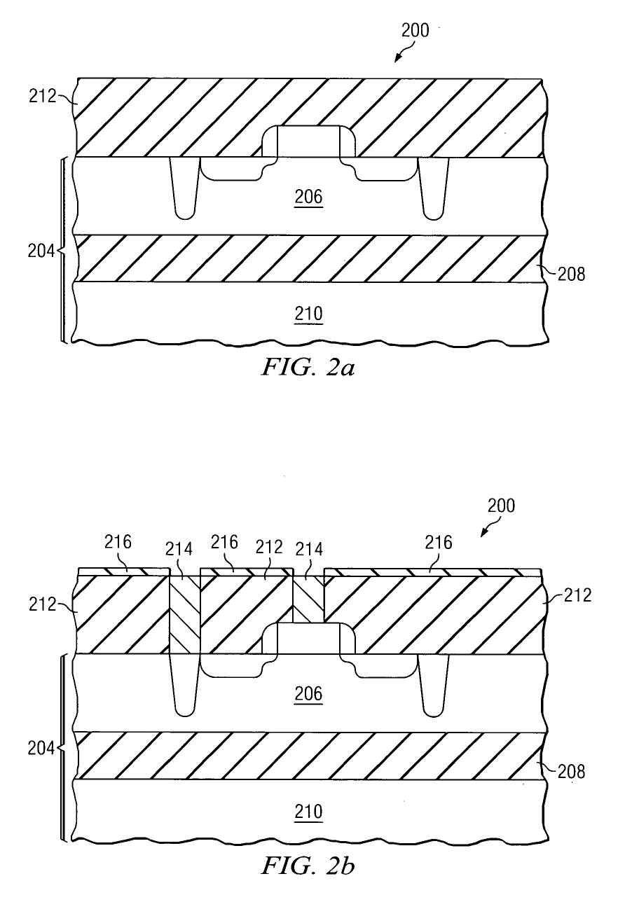

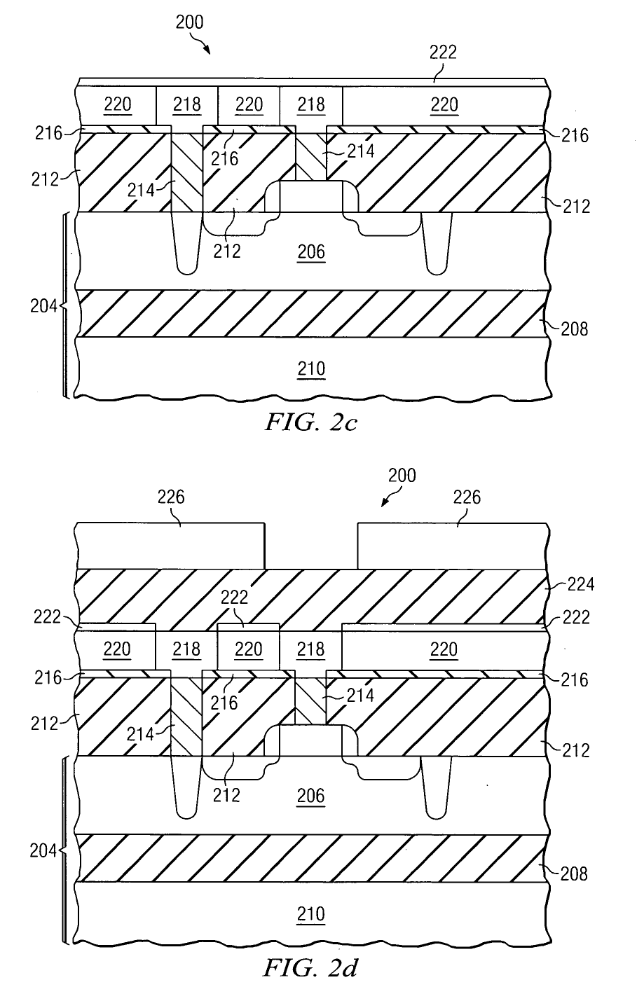

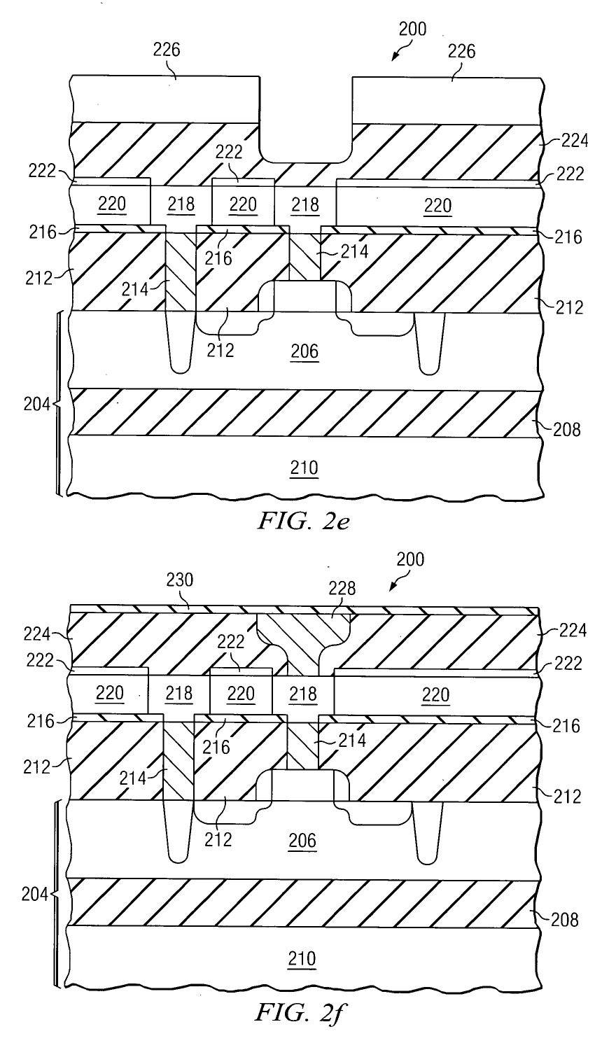

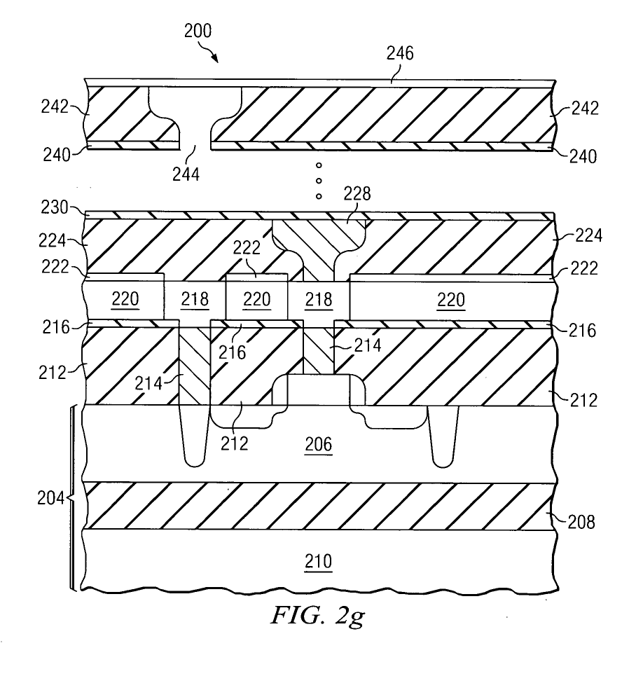

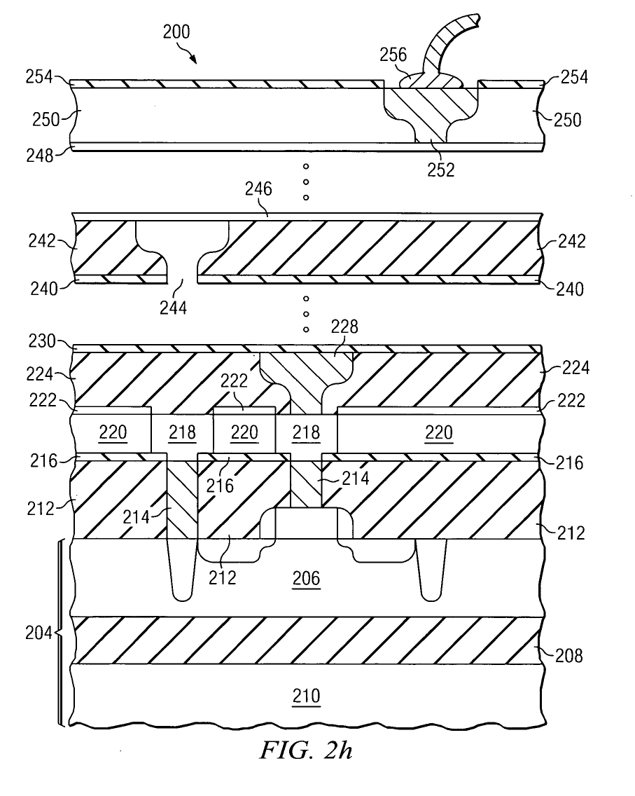

Turning now to FIGS. 2a through 2h, further processing details will be provided for an exemplary device 200. For clarity, device 200 will be illustrated as having only three metal patterns. This is simply to illustrate the basic processing steps. In actual application, there would be two or more of each type of metal pattern and dielectric layer described herein. In fact, as the number of metal pattern layers increases, the advantageous features of the present invention become more pronounced.

In FIG. 2a, which illustrates an intermediate step in the formation of integrated device 200, transistor 202 has been formed within and on substrate 204. In the illustrated embodiment, substrate 204 is a silicon-on-insulator substrate including a semiconductor layer 206 formed over a buried oxide layer 208 that is formed on a supporting substrate 210. In other embodiments, substrate 204 could be a single-crystal silicon wafer or other appropriate material providing sufficient mechanical and electrical characteristics. In presently contemplated embodiments, transistor 202 preferably has a gate size of 0.13 microns, 90 nm, or less. This is because the dense packing and high switching speeds of small geometry devices particularly require the advantageous features offered by the present invention. That being said, it is contemplated that the present invention would apply to larger geometry devices as well, particularly when a combination of good mechanical and electrical characteristics is required of the metallic interconnect stack. Note that although transistor 2 is illustrated as a conventional MOSFET transistor, the teachings of the present invention are not limited to MOSFET transistors or to planar transistors. Rather the present invention applies equally to any electrical component or structure in which it is desired to make electrical connection.

Dielectric layer 212 has been formed above the substrate to insulate MOSFET 2 from subsequently formed metal layers. In the illustrated embodiment, dielectric layer 212 is preferably formed by CVD deposition of a phosphorous doped silicon glass (“PSG”) layer to a thickness of about 4,000 to 12,000 Angstroms. Alternatively, dielectric layer 212 could be a CVD or PECVD deposited SiO₂. In other embodiments, dielectric layer 212 could be formed from a low k dielectric material.

Contact openings are formed in dielectric layer 212 and are filled with a conductive material as shown in FIG. 2b. In the preferred embodiments, the contact opening are filled with a conductive plug 214. Plug 214 may comprises tungsten, aluminum, doped polysilicon, or some other appropriate conductive material. Preferably, plug 214 will also include adhesion and barrier layers (not shown), such as titanium and titanium nitride, respectively, for improved device characteristics. In other embodiments, a damascene process could be employed in lieu of plugs 214. In such a process, trenches and holes are formed in dielectric layer 214 and are subsequently filled by growing or depositing a conductive material such as copper within the trenches and holes. In the embodiment illustrated in FIG. 1, the contact holes are filled using plug technology.

Either before or after filling the contact holes in dielectric layer 212 with plugs 214, an etch stop layer 216 is formed above dielectric layer 212. Etch stop layer 216, which may also serve to provide improved adhesion for subsequently formed layers is preferably formed of e.g., SiC, SiCO, SiCN, or combinations thereof. In the illustrated embodiment, layer 216 is deposited using CVD or PECVD to a thickness of 200 to 1,000 Angstroms.

In a first preferred embodiment, first metal pattern is formed using a single damascene process. In this process, dielectric layer 220 is formed first and trenches are formed within the dielectric layer, preferably using conventional photolithographic and etching techniques. Etch stop layer 216 preferably prevents the step of etching dielectric layer 220 from etching or otherwise negatively impacting underlying dielectric layer 212. Note that prior to forming metal pattern 218, etch stop layer 216 will need to be selectively removed in those regions where it is desired to make electrical contact between, e.g., plugs 214 and first metal pattern 218. After trenches are formed in dielectric layer 220, metal pattern 218 is formed by depositing metal into the trenches. Preferably, metal pattern 218 is formed of copper or a copper aluminum alloy that is blanket deposited over the top surface of the device, and subsequently planarized so that it remains only in the trenches. The planarization is preferably performed using a chemical mechanical polishing (CMP) process. After metal patterns 218 have been formed within dielectric layer 220, etch stop layer 222 is deposited over the top surface. Etch stop layer 222 is preferably although not necessarily the same material as used for etch stop layer 216.

The formation of a second metal pattern 228 will now be described with reference to FIG. 2d. This second metal pattern is preferably formed using a dual damascene process in which vias (or electrical connections to first metal pattern) are formed and the metal interconnects are formed in an integrated fashion within a single dielectric layer. As discussed above, circuit performance characteristics dictate that parasitic capacitance between metal layers be minimized. As such, the electrical characteristics of the inter-level dielectrics play a crucial role and extremely low k dielectrics are particularly desirable.

In FIG. 2d, extremely low k dielectric layer 224 has been deposited to a thickness of approximately 2,000 to 7,000 Angstroms above etch stop 222. Note that, prior to the deposition of dielectric layer 224, etch stop 222 has been removed in those regions where it is desirable to make electrical contact to the underlying metal pattern 218. As discussed above, dielectric layer 224 is preferably spun on or CVD deposited using one or more of the various well-known extremely low k dielectrics such as an oxide and methylsilsesquioxane (“MSQ”) hybrid, an MSQ derivative, porogen/MSQa hybrid, an Oxide/Hydrogen silsesquioxane (“HSQ,” also known as Hydridosilsesquioxane) hybrid, an HSQ derivative, a porogen/HSQ hybrid, and the like. Other materials, such as nanoporous silica, xerogel, poly tetra fluoro ethylene (“PTFE”), and low k dielectrics such as SiLK available from Dow Chemicals of Midland, Mich., Flare, available from AlliedSignal of Morristown, N.J., and Black Diamond, available from Applied Materials of Santa Clara, Calif., may also be employed. Other alternative materials may be identified through routine experimentation or may be discovered at some future date; those alternatives are considered within the scope of the present invention as well. In the preferred embodiments, dielectric layer 224 preferably has a dielectric constant of below 2.8 and more preferably in the range of 2.2 to 2.5.

Photoresist 226 is formed over dielectric layer 224 and patterned using conventional photolithographic techniques, also as illustrated in FIG. 2d. This photoresist layer 226 will be used to trench vias in dielectric layer 224 in order to make electrical contact with metal interconnects 218. For clarity, only one opening in photoresist 226 is shown in FIG. 2d. One skilled in the art will recognize that multiple openings will in reality be formed in order to make multiple contacts to the underlying metal layer 218.

Extremely low k dielectric layer 224 is then etched away in the region beneath the opening in photoresist 226, as shown in FIG. 2e. Dielectric layer 224 is anisotropically etched, preferably by plasma enhanced dry etch. Dielectric layer 224 is etched back to form a trench in which will be subsequently formed a metal interconnect, as described below.

After etching the trench into dielectric layer 224, photoresist 226 is removed and a second photoresist layer (not shown) in formed over the device, this second photoresist layer having an opening in it corresponding to the via to be etched into dielectric layer 224. A second etch step is carried out, resulting in the trench and via profile shown in FIG. 2f. The trench and via are then filled with copper or a copper alloy in a blanket deposition process which also covers the surrounding portions of dielectric layer 224. A chemical mechanical polish (CMP) step is next carried out in which the excess copper material is removed from all regions except for within the via and trench, resulting in the metal interconnect 228 illustrated in FIG. 2f. A third etch stop layer 230 is then applied across the surface of the device, much as described above.

Several metal layers can be formed on the device using the extremely low k dielectric material and dual damascene process described above. For clarity, however, only one such layer is shown in the Figures.

FIG. 2g illustrates the integrated circuit at a subsequent intermediate step in processing. Note the ellipses, which indicate (as discussed above) that numerous metal layers can be formed above metal interconnect 228 using the extremely low k dielectric materials discussed above as the inter-level dielectric. FIG. 2g picks up in the process flow where an etch stop layer 240 has been formed above an underlying dielectric layer. In the middle or intermediate layers, the electrical characteristics of the dielectric layers are still important, but perhaps not as critical as for the lower level metals. As such, a higher dielectric constant material (than layer 224) could be employed as the inter-level dielectric layer 242. In preferred embodiments, dielectric layer 242 could be formed of a material having a dielectric constant of between 2.5 and 4.2 and even more preferably in the range of between 2.5 and 3.3. Dielectric layer 242 is preferably formed of an oxide and methylsilsesquioxane (“MSQ”) hybrid, an MSQ derivative, porogen/MSQa hybrid, an Oxide/Hydrogen silsesquioxane (“HSQ,” also known as Hydridosilsesquioxane) hybrid, an HSQ derivative, a porogen/HSQ hybrid, and the like. Other materials, such as nanoporous silica, xerogel, poly tetra fluoro ethylene (“PTFE”), and low k dielectrics such as SiLK available from Dow Chemicals of Midland, Mich., Flare, available from AlliedSignal of Morristown, N.J., and Black Diamond, available from Applied Materials of Santa Clara, Calif., may also be employed. The layers are preferably deposited using a chemical vapor deposition (“CVD”) or spin-on coating technique, although other deposition techniques could be employed as well. In the presently contemplated preferred embodiments, the middle-level dielectric layers are preferably deposited to a thickness of approximately 2,000 to 7,000 Angstroms. In other embodiments, dielectric layer 242 may have a dielectric constant similar to the extremely low dielectric constant for layer 224.

As also shown in FIG. 2g, etch stop layer 240 has openings etched therein in those regions where it is desired to make electrical contact to underlying interconnects (not shown). Using a dual damascene process, as described above, vias and trenches can be formed in dielectric layer 242 and filled with metal to form metal interconnect 244. Finally, etch stop layer 246 is shown deposited above dielectric layer 242 and metal pattern 244.

As above, several metal layers can be formed on the device using the middle range extremely low k dielectric material and dual damascene process described above in FIG. 2g. For clarity, only one such layer is shown, however. In FIG. 2h, this is shown by the ellipses that indicate several metal layers and inter-level dielectric layers are contemplated, but not shown. As illustrated, in a subsequent intermediate processing step, etch stop layer 248 has been deposited over the top of the underlying metal interconnects and dielectric material. Dielectric layer 250 is representative of upper level inter-level dielectrics. In the upper metal layers, electrical characteristics of the inter-level dielectrics, while still important, are not as critical as for the lower level and middle level dielectric layers. As such, materials can be employed that provide acceptable dielectric characteristics with substantially better mechanical characteristics. Preferably, dielectric layer 250 is formed of a material having a dielectric constant in the range of about 3.0 to 4.2. One exemplary such material is undoped silicon glass (USG) that can be CVD deposited onto the substrate surface and subsequently patterned. In other instances, FSG or other well-known alternatives, having acceptably low k characteristics, may be employed. While the layer thickness is a matter of design choice and process control, the upper layers would be typically deposited to a thickness in the range of from 6,000 to 15,000 Angstroms.

As shown, dielectric layer 250 is also etched to form vias and trenches for metal layer 252. Preferably, dielectric layer 250 is etched using conventional anisotropic etch processes, such as plasma enhanced dry etching. Note that the trench patterns formed in metal layer 252 are shown as larger than the patterns in metal layer 244 and 228. While not necessary for the present invention, this is preferable as the upper level metal layers are more likely to be required to carry large currents and voltages. Passivation layer 254 is formed above the top level metal. As discussed above with respect to FIG. 1, passivation could be accomplished by a layer comprising silicon nitride (preferably plasma enhanced silicon nitride), undoped silicon glass (USG), or a combination of the two.

Also as shown in FIG. 2h, and assuming that metal layer 252 is the top metal layer, bond pads can be formed on or integral to metal layer 252. Openings in passivation layer 254 are formed in order to electrically connect the device to other circuit components. In the illustrated embodiment, a bond wire 256 is used to electrically connect the integrated circuit to external devices (including e.g., signal sources and voltage sources). Alternatively, the integrated circuit could be electrically connected to external devices using flip-chip technology, solder bump technology, and other well-known alternatives.

In the foregoing specification, the invention has been described with reference to specific embodiments. However, various modifications and changes can be made by one skilled in the art without departing from the scope of the present invention. Accordingly, the specification and figures are to be regarded in an illustrative rather than a restrictive sense, and all such modifications are intended to be included within the scope of the present invention.

What is claimed is:

1. An integrated circuit comprising:
a substrate having a top surface;
a first dielectric layer formed above the substrate having a trench formed therein, the first dielectric layer having a first dielectric constant;
a first metal layer formed within the trench of the first dielectric layer;
a second dielectric layer formed above the first metal layer and having a trench formed therein, the second dielectric layer having a second dielectric constant;
a second metal layer formed within the trench of the second dielectric layer;
a third dielectric layer formed above the second metal layer and having a trench formed therein, the third dielectric layer having a third dielectric constant; and
a third metal layer formed within the trench of the third dielectric layer.

2. The integrated circuit of claim 1 wherein said first dielectric layer has a dielectric constant of less than 2.8, said second dielectric layer has a dielectric constant of between 2.8 and 3.3, and said third dielectric layer has a dielectric constant of above 3.0.

3. The integrated circuit of claim 1 wherein said first dielectric layer comprises a material selected from the group consisting of an oxide and methylsilsesquioxane (“MSQ”) hybrid, an MSQ derivative, porogen/MSQa hybrid, an Oxide/Hydrogen silsesquioxane (“HSQ”) hybrid, an HSQ derivative, and a porogen/HSQ hybrid.

4. The integrated circuit of claim 1 wherein said second dielectric layer comprises a material selected from the group consisting of an oxide and methylsilsesquioxane (“MSQ”) hybrid, an MSQ derivative, porogen/MSQa hybrid, an Oxide/Hydrogen silsesquioxane (“HSQ”) hybrid, an HSQ derivative, and a porogen/HSQ hybrid.

5. The integrated circuit of claim 1 wherein said third dielectric layer comprises a material selected from the group consisting of silicon glass, undoped silicon glass, fluorine doped silicon glass, and high-density chemical vapor deposition (HPVCD) silicon oxide.

6. The integrated circuit of claim 1 further comprising a first transistor and a second transistor formed within the substrate and wherein the first and second transistors are electrically coupled through the metal layers.

7. A method of forming an integrated circuit comprising:
forming a transistor within a substrate;
depositing a first dielectric material over the transistor;
forming an opening to the transistor in the first dielectric material;
depositing a first metal pattern within the first dielectric material;
depositing a second dielectric material, having a higher dielectric constant than the first dielectric material, over the first metal pattern;
forming an opening to the first metal pattern in the second dielectric material;
depositing a second metal pattern within the second dielectric material;
depositing a third dielectric material, having a higher dielectric constant than the first and second dielectric materials, over the second metal pattern;
forming an opening to the second metal pattern in the third dielectric material; and
depositing a third metal pattern in the third dielectric material.

8. The method of claim 7 wherein depositing a first dielectric material comprises spin-on depositing a material having a dielectric constant of below 2.8, depositing a second dielectric material comprises spin-on depositing a material having a dielectric constant of between 2.5 and 3.3, and depositing a third dielectric material comprises spin-on depositing a material having a dielectric constant of above 3.0.

9. The method of claim 7 further comprising depositing a fourth dielectric material, having a higher dielectric constant that is different than the first, second, and third dielectric materials, over the third metal pattern.

10. The method of claim 7 wherein depositing a first dielectric material comprises depositing a material selected from the group consisting of an oxide and methylsilsesquioxane (“MSQ”) hybrid, an MSQ derivative, porogen/MSQa hybrid, an Oxide/Hydrogen silsesquioxane (“HSQ”) hybrid, an HSQ derivative, and a porogen/HSQ hybrid.

11. The method of claim 10 wherein depositing a second dielectric material comprises depositing a material selected from the group consisting of an oxide and methylsilsesquioxane (“MSQ”) hybrid, an MSQ derivative, porogen/MSQa hybrid, an Oxide/Hydrogen silsesquioxane (“HSQ”) hybrid, an HSQ derivative, and a porogen/HSQ hybrid.

12. An electrical device comprising:
a plurality of metal layers formed one atop the other;
a plurality of inter-level dielectric layers, each such inter-level dielectric layer serving to electrically insulate at least one metal layer from at least one other metal layer;
wherein the plurality of inter-level dielectric layers includes:
at a lower region, inter-level dielectric layers having a first dielectric constant,
at a middle region, inter-level dielectric layers having a second dielectric constant; and
at an upper region, inter-level dielectric layers having a third dielectric constant.

13. The electrical device of claim 12 wherein:
the first dielectric constant is below 2.8;
the second dielectric constant is between 2.5 and 3.3; and
the third dielectric constant is above 3.0.

14. The electrical device of claim 12 wherein the lower region inter-level dielectric layer comprises a material selected from the group consisting of an oxide and methylsilsesquioxane (“MSQ”) hybrid, an MSQ derivative, porogen/MSQa hybrid, an Oxide/Hydrogen silsesquioxane (“HSQ”) hybrid, an HSQ derivative, and a porogen/HSQ hybrid.

15. The electrical device of claim 12 wherein the middle region inter-level dielectric layer comprises a material selected from the group consisting of an oxide and methylsilsesquioxane (“MSQ”) hybrid, an MSQ derivative, porogen/MSQa hybrid, an Oxide/Hydrogen silsesquioxane (“HSQ”) hybrid, an HSQ derivative, and a porogen/HSQ hybrid.

16. The electrical device of claim 12 wherein the upper region inter-level dielectric layer comprises a material selected from the group consisting of undoped silicon glass, doped silicon glass, and silicon oxide.

17. The electrical device of claim 12 wherein the first dielectric constant is lower than the second and third dielectric constants.

18. The electrical device of claim 12 wherein the second dielectric constant is lower than the first and third dielectric constants.

19. An integrated circuit comprising:
a substrate;
a plurality of transistors formed on the substrate;
a plurality of isolation regions electrically isolating at least one of the plurality of transistors from at least one other of the transistors;
a first dielectric layer, having a first dielectric constant, formed above the substrate having formed therein a via to a transistor, and an interconnect structure;
a second dielectric layer, having a second dielectric constant, formed above the first dielectric layer and having formed therein a second interconnect structure; and
a third dielectric layer, having a third dielectric constant, formed above the second dielectric layer and having formed therein a third interconnect structure.

20. The integrated circuit of claim 19 wherein the transistors have gate lengths of 130 microns or less.

21. The integrated circuit of claim 19 wherein the substrate is a silicon-on-insulator substrate.

22. The integrated circuit of claim 19 wherein the first and second dielectric layers comprise a material selected from the group consisting of an oxide and methylsilsesquioxane (“MSQ”) hybrid, an MSQ derivative, porogen/MSQa hybrid, an Oxide/Hydrogen silsesquioxane (“HSQ”) hybrid, an HSQ derivative, a porogen/HSQ hybrid, nanoporous silica, xerogel, and Poly tetra fluoro ethylene (“PTFE”).

23. The integrated circuit of claim 19 further comprising a first insulator layer between the substrate and the first dielectric layer.

24. The integrated circuit of claim 19 wherein the via connects to a doped region of a transistor.

25. The integrated circuit of claim 19 wherein the second dielectric constant is lower than the third dielectric constant and the first dielectric constant is lower than both the second and third dielectric constants.
